(19) United States
(12) Patent Application Publication
(10) Pub. No.: US 2003/0160311 A1
(43) Pub. Date: Aug. 28, 2003

(54) Stacked die semiconductor device

(76) Inventors: Aminuddin Ismail, Selangor (MY); Wai Yew Lo, Selangor (MY); Kim Heng Tan, Kaula Lumpur (MY)

Correspondence Address: MOTOROLA, INC., CORPORATE LAW DEPARTMENT - #56-238, 3102 NORTH 56TH STREET, PHOENIX, AZ, 85018, US

(21) Appl. No.: 10/085,389

(22) Filed: Feb. 28, 2002

(51) Int. Cl. H01L 23/02

(52) U.S. Cl. 257/678

(57) ABSTRACT

A stacked multichip package (100) has a base carrier (102) having a top side (108) and a bottom side (110), a bottom integrated circuit die (104) having a bottom surface attached to the base carrier top side (108), and a top integrated circuit die (106 attached to a top surface of the bottom die (104). The top die (106) is attached to the bottom die (104) with a die attach material (118) having particles (120) blended therein is dispensed onto the top surface of the bottom die. The particles (120) blended into the die attach material (118) maintain a predetermined spacing between the bottom die and the top die so that wirebonds connecting the bottom die (104) to the base carrier (102) are not damaged when the top die (106) is attached to the bottom die (104).

### BACKGROUND OF THE INVENTION

The present invention relates to integrated circuits and a method of packaging integrated circuits and, more particularly, to stacked multi-chip package type integrated circuits.

An integrated circuit (IC) die is a small device formed on a semiconductor wafer, such as a silicon wafer. Such a die is typically cut from the wafer and attached to a base carrier for interconnect redistribution. Bond pads on the die are then electrically connected to the leads on the carrier via wire bonding. The die and wire bonds are encapsulated with a protective material such that a package is formed. The leads encapsulated in the package are redistributed in a network of conductors within the carrier and end in an array of terminal points outside the package. Depending on the package types, these terminal points may be used as-is, such as in TSOP, or further processed, such as attaching spherical solder balls for a Ball Grid Array (BGA). The terminal points allow the die to be electrically connected with other circuits, such as on a printed circuit board. In subsequent examples, a MAPBGA is used to illustrate the invention disclosed herein.

With the goal of increasing the amount of circuitry in a package, but without increasing the area of the package so that the package does not take up any more space on the circuit board, manufacturers have been stacking two or more die within a single package. Such devices are sometimes referred to as stacked multichip packages. FIG. 1 shows a first conventional stacked multichip package 10. The package 10 includes a first or bottom die 12 attached to a base carrier 14 (in this example, a MAPBGA substrate) with a first adhesive layer 16. A second or top die 18 is attached to the bottom die 12 with a second adhesive layer 20 similar to the first adhesive layer 16. The bottom and top dice 12, 18 are electrically connected to the base carrier 14 with wires 22 and 24, respectively, via wirebonding. Terminals 26, in this case spherical solder ball terminals, are connected to a network or redistribution layer (not shown) of the base carrier 14. The bottom and top dice 12, 18 and the wires 22, 24 are sealed with a resin 28, thus forming the stacked multichip package 10. In order to allow the bottom die 12 to be wirebonded to the leads of the base carrier 14, the top die 18 must be smaller than the bottom die 12.

FIG. 2 shows a second conventional stacked multichip package 30. The second package 30 includes a first or bottom die 32 attached to a base carrier or substrate 34 with a first adhesive layer 36. Bond pads on the bottom die 32 are electrically connected to leads on the substrate 34 with first wires 38 via wirebonding. A spacer 40, typically made of bare silicon, is attached to the bottom die 32 with a second adhesive layer 42. A third or top die 44 is attached to the spacer 40 with a third adhesive layer 46.

The top die 44 is almost the same size or bigger than the bottom die 32. In such a situation, wirebonding of the bottom die 32 is impossible if the top and bottom dice 32, 44 are attached as shown in FIG. 1 (i.e., without the spacer 40). However, as shown in the drawing, the spacer 40 is smaller than the bottom die 32 so that the bottom die 32 may be wirebonded without obstruction. Thus, bond pads on the top die 44 are electrically connected to the substrate 24 with second wires 48 via wirebonding.

The total thickness of the spacer 40 and the second and third adhesive layers 42 and 46 must also be large enough so that the wires 38 connected to the bottom die 32 are not disturbed when the top die 44 is attached to the spacer 40. Spherical solder ball terminals 50 are connected to a wiring layer (not shown) of the substrate 34. The bottom die 32, top die 44, spacer 40 and the wires 38, 48 are sealed with a resin 52, thus forming the stacked multichip package 30. While this solution allows two die with almost the same size to be packaged together, the spacer 40 increases the process lead time, cost and size (height) of the package 30.

It would be desirable to be able to stack two or more die of the same size, or an even larger top die in a single package without unduly increasing the size of the resulting package and without the requirement of a spacer.

### BRIEF DESCRIPTION OF THE DRAWINGS

The foregoing summary, as well as the following detailed description of preferred embodiments of the invention, will be better understood when read in conjunction with the appended drawings. For the purpose of illustrating the invention, there is shown in the drawings embodiments that are presently preferred. It should be understood, however, that the invention is not limited to the precise arrangements and instrumentalities shown. In the drawings:

FIG. 1 is an enlarged side view of a first conventional stacked multichip package;

FIG. 2 is an enlarged side view of a second conventional stacked multichip package;

FIG. 3 is an enlarged side view of a stacked multichip package in accordance with a first embodiment of the invention;

FIG. 4 is a block diagram of a first system for forming a die attach material in accordance with the present invention;

FIG. 5 is a block diagram of a second system for forming a die attach material in accordance with the present invention; and

FIG. 6 is a block diagram of a third system for forming a die attach material in accordance with the present invention.

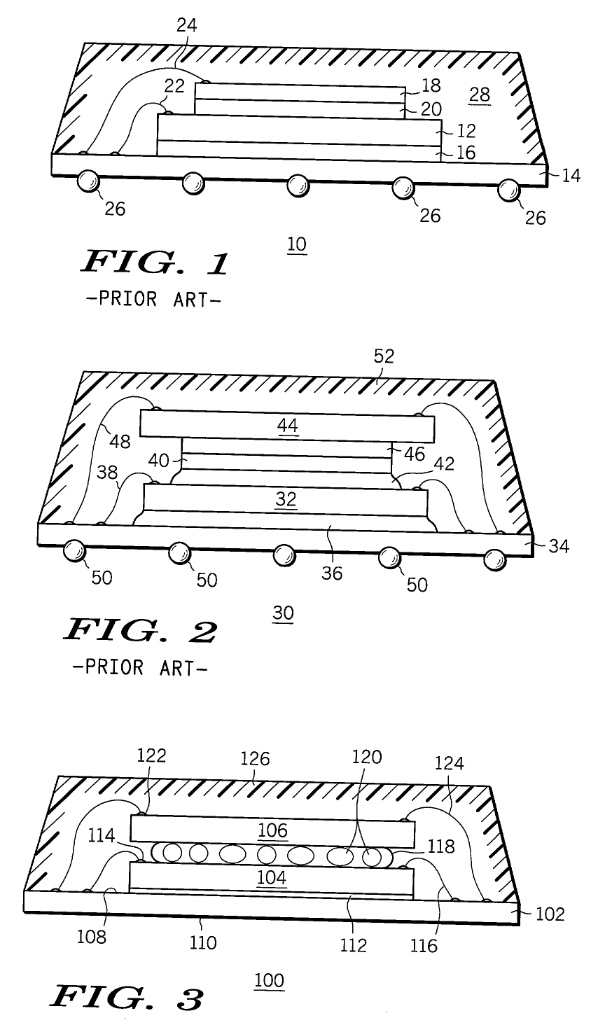

### DETAILED DESCRIPTION OF PREFERRED EMBODIMENTS

The detailed description set forth below in connection with the appended drawings is intended as a description of the presently preferred embodiments of the invention, and is not intended to represent the only forms in which the present invention may be practiced. It is to be understood that the same or equivalent functions may be accomplished by different embodiments that are intended to be encompassed within the spirit and scope of the invention. For simplicity, examples used to illustrate the invention refer only to a package having two stacked dice. However, the same invention in fact can be applied to packages having more than two stacked dice.

Certain features in the drawings have been enlarged for ease of illustration and the drawings and the elements thereof are not necessarily in proper proportion. However, those of ordinary skill in the art will readily understand such details. In the drawings, like numerals are used to indicate like elements throughout.

In order to provide a stacked multichip package in which a top die is about the same size or larger than a bottom die, the present invention is a stacked multichip package, including a base carrier having a top side and a bottom side, a bottom integrated circuit die, a die attach material, and a top integrated circuit die. The bottom integrated circuit die has a bottom surface attached to the base carrier top side, and an opposing, top surface having a peripheral area including a plurality of first bonding pads and a central area. The die attach material has particles blended therein and is dispensed onto the top surface of the bottom die in the central area. The top integrated circuit die is positioned over the bottom die and a bottom surface of the top die is attached to the top surface of the bottom die via the die attach material. The particles blended into the die attach material maintain a predetermined spacing between the bottom die and the top die.

The present invention also provides a stacked multichip package including a base carrier, a bottom integrated circuit die, a top integrated circuit die, an adhesive material, and an encapsulant. The base carrier has a top side and a bottom side, the top side including a plurality of first leads and a plurality of second leads. The bottom die has a bottom surface attached to the base carrier top side, and an opposing, top surface. The top surface of the bottom die has a peripheral area including a plurality of first bonding pads and a central area. The bottom die is electrically connected to the base carrier with first wires. The first wires have first ends electrically connected to respective ones of the first bonding pads and second ends electrically connected to respective ones of the first leads.

The adhesive material has particles blended in it. The adhesive material and the particles are dispensed on the top surface of the bottom die in the central area. The top integrated circuit die is positioned over the bottom die and a bottom surface of the top die is attached to the top surface of the bottom die with the adhesive material. The particles blended into the adhesive material maintain a predetermined spacing between the bottom die and the top die so that the first wires are not damaged when the top die is attached to the bottom die.

The top die includes a plurality of second bonding pads located on a top surface thereof and is electrically connected to the base carrier with second wires. The second wires have first ends electrically connected to respective ones of the second bonding pads and second ends electrically connected to respective ones of the second leads. The encapsulant covers the first and second dice, the first and second wires, and at least a portion of the top side of the base carrier.

The present invention also provides a method of making a stacked multichip package comprising the steps of:

attaching a bottom integrated circuit die to a base carrier, the bottom die having a bottom surface and a top surface, the top surface having a central area and a peripheral area, the peripheral area including a plurality of first bonding pads, wherein the bottom surface of the bottom die is attached to a top side of the base carrier;

electrically connecting the bottom die to the base carrier by wirebonding first wires to respective ones of the plurality of first bonding pads of the bottom die and to corresponding first leads on the top side of the base carrier;

dispensing an adhesive material onto the central area of the top surface of the bottom die;

dispensing a plurality of particles onto the adhesive material to provide the adhesive material with a predetermined height;

attaching a bottom surface of a top die to the top surface of the bottom die with the adhesive material, the top die having a plurality of second bonding pads located on a top surface thereof, wherein the dispensed particles cause the top die to be spaced from the bottom die such that the top die does not contact the first wires; and

electrically connecting the top die to the base carrier by wirebonding second wires to respective ones of the plurality of second bonding pads and to corresponding second leads on the base carrier.

Referring now to FIG. 3, an enlarged side view of a stacked multichip package 100 in accordance with the present invention is shown. The stacked multichip package 100 includes a base carrier or substrate 102, a bottom integrated circuit die 104 and a top integrated circuit die 106. The substrate 102 provides an interconnect network for electrically connecting the bottom and top die 104 and 106 to each other and to other components or devices.

The bottom die 104 and the top die 106 preferably have substantially the same length and width dimensions. However, the top die 106 may be somewhat larger or somewhat smaller than the bottom die 104. For example, typical bottom and top die sizes may range from 4 mm×4 mm to 12 mm×12 mm. The bottom and top dice 104, 106 may also have the same thickness, however, this is not required. Depending on the required final package outline thickness, the bottom and top dice 104, 106 may have a thickness ranging from about 6 mils to about 21 mils. Each of the substrate 102, the bottom die 104, and top die 106 are of a type well known to those of ordinary skill in the art, and further description of these components is not required for a complete understanding of the present invention.

The substrate 102 has a top side 108 and a bottom side 110. The bottom die 104 has a bottom surface and a second, opposing top surface. The bottom surface of the bottom die 104 is attached to the top side 108 of the substrate 102. Preferably, the bottom die 104 is attached to the substrate 102 with a first adhesive material layer 112. The first adhesive material layer 112 may be any suitable adhesive material, such as an adhesive tape, a thermo-plastic adhesive, an epoxy material, or the like. Such adhesives for attaching an integrated circuit die to a substrate are well known to those of skill in the art.

The top surface of the bottom die 104 has a peripheral area including a plurality of first bonding pads 114 and a central area. The bottom die 104 is electrically connected to leads (not shown) on the substrate 102 with first wires 116. More particularly, one end of the first wires 116 is electrically connected to the bonding pads 114 on the top surface of the bottom die 104, and opposing ends of the first wires 116 are wirebonded to the leads located on the top surface 108 of the substrate 102. Suitable bond wires typically comprise a conductive metal such as copper or gold.

The top die 106 is attached to the bottom die 104 with an adhesive material 118. More particularly, a bottom surface of the top die 106 is attached to the central area of the top surface of the bottom die 104 with the adhesive material 118. The adhesive material 118 is dispensed in an uncured or soft phase on to the central area on the top surface of the bottom die 104 and then the top die 106 is placed on top of the bottom die 104 and the adhesive material 118. The adhesive material 118 is then cured through exposure and/or heating for a specified time period. Once cured, the adhesive material 118 provides the mechanical strength required to hold the top die 106 to the bottom die 104.

In accordance with the present invention, the adhesive material 118 includes a plurality of particles 120 blended therein in order to maintain a predetermined spacing between the bottom die 104 and the top die 106 so that the wirebonds of the wires 122 are not damaged when the top die 106 is attached to the bottom die 104. The adhesive material 118 preferably comprises any of the typical adhesives used to attach one die to another die, so long as it is filled with particles sufficient to provide the aforementioned predetermined spacing. Typical adhesives are epoxy, cyanate ester and polyimide.

The particles 124 are sized and shaped to provide adequate spacing between the bottom die 104 and the top die 106 when the top die 106 is attached to the bottom die 104, as shown in FIG. 3, such that when the top die 106 is attached to the bottom die 104, the wirebonds of the first wires 122 are not damaged. The particles 124 are preferably generally circular in shape and have a diameter ranging from about 30 um to about 96 um, and preferably of about 60 um. However, the particles 124 may have other shapes, such as oval, rectangular, or the like, and do not all have to be the same shape or of uniform shape, so long as they provide adequate spacing between the bottom die 104 and the top die 106 to protect the wirebonds. The particles 120 are preferably formed of a stable and inert material that can be mixed with the aforementioned adhesives but will not damage the top surface of the bottom die 104 when some force is applied, such as during attachment of the top die 106. Presently preferred materials are silica and Teflon. However, the particles 120 could be formed of other materials or blends of materials. The ratio of particles and resin of the adhesive material preferably is about 1:3 by weight in order to balance between dispensability and thermal mismatch of epoxy with the die.

The top die 106 includes a plurality of second bonding pads 122 located in a peripheral area on a top surface thereof. The top die 106 is electrically connected to the base carrier 102 with second wires 124. The second wires 124 have first ends electrically connected to the second bonding pads 122 and second ends electrically connected to second leads (not shown) on the base carrier 102. The second wires 124 are preferably wirebonded to the second bonding pads 122 and the second leads.

An encapsulant 126 such as resin covers the bottom and top dice 104, 106, the first and second wires 116, 124 and at least a portion of the top side of the base carrier 102.

The adhesive material 118 may be formed on the bottom die 104 in a number of ways, such as with a needle and syringe or an epoxy dam writer, as are known by those of skill in the art. However, the size of the needle through which the epoxy or bead material is dispensed onto the bottom die 104 will depend to an extent on size of the particles 120.

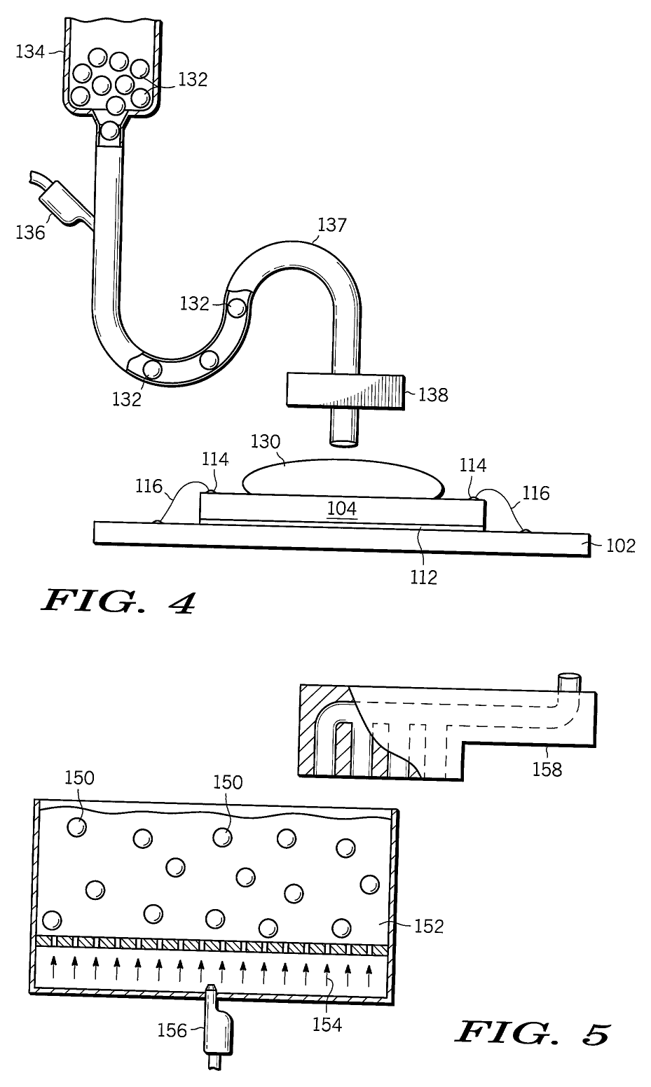

Referring now to FIG. 4, a first method of dispensing the die attach material 118 onto the central area of the top surface of the bottom die 104 in accordance with the present invention is shown. In a first dispensing step, an adhesive material 130 such as an epoxy, cyanate ester or polyimide is dispensed onto the central area of the top surface of the bottom die 104. Then, in a second dispensing step, a plurality of particles 132 are dispensed onto the adhesive material 130 to provide the adhesive material 130 with a predetermined height. More particularly, the particles 132 are held in a container 134 and forced, using compressed air, through a tube 137 to an X, Y stage movement dispenser 138, from which the particles 132 are dispensed onto the adhesive material 130. The compressed air may be injected into the tube 137 via a nozzle 136. As previously discussed, the particles 132 insure a predetermined distance is maintained between the bottom die 104 and the top die 106 when the top die 106 is attached to the bottom die 104 so that the wirebonds of the wires 116 are not damaged.

Referring now to FIG. 5, a second method of dispensing adhesive material and particles onto the bottom die 104 is shown. In this embodiment, a plurality of particles 150 are stored in a fluid bath 152. Air, represented by arrows 154, is forced into the bath 152 via a nozzle 156. The particles 150 are picked up with a particle pickup arm 158 using vacuum pressure. The pickup arm 158 then moves over top of the bottom die 104 and dispenses the particles onto the adhesive material (without particles) already dispensed onto top surface of the bottom die 104. The particles 150 are released onto the top surface of the bottom die 104 by releasing or lowering the vacuum pressure in the pickup arm 158.

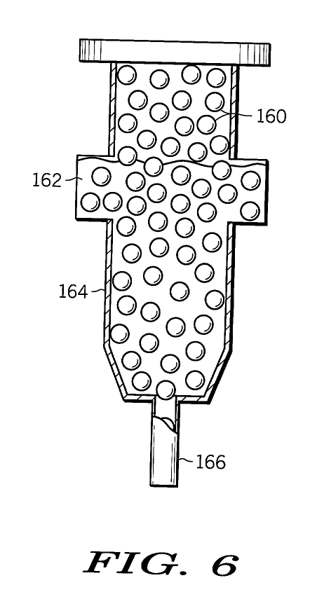

Referring now to FIG. 6, a third method of dispensing adhesive material and particles onto the bottom die 104 is shown. According to the third method, particles 160 are blended with adhesive material 162 in a container 164 and then the blended adhesive material and particles are dispensed onto the central area of the bottom die in a single dispensing step. The blended adhesive and particles can be dispensed onto the bottom die 104 via a needle 166. The container 164 is preferably connected to an X, Y stage so that it can move from die to die dispensing the blended adhesive material in a manner known to those of skill in the art.

After the top die has been attached to the bottom die 104 and the adhesive material has cured, the top die 106 can then be electrically connected to the substrate 102 via wirebonding the second wires 124 (FIG. 3) to the substrate 102. Then, as discussed above, an encapsulant 126 is formed over the bottom and top dice 104, 106, the first and second wires 116, 124 and at least a portion of the top side of the base carrier 102.

The resulting stacked multichip package has two, almost same-sized stacked die, yet the overall package height is less than the package height of the prior art stacked die package that includes a dummy, spacer die. The cost of the stacked multichip package is also reduced because a dummy die is not required and the step of attaching the dummy die is not required.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. For example, the present invention is not limited to a package with two stacked dice, but can be applied to a package with multiple stacked dice. Further, the present invention is not limited to any single wire bonding technique or to a particular package. That is, the invention is applicable to all wire bonded package types, including but not limited to BGA, QFN, QFP, PLCC, CUEBGA, TBGA, and TSOP. In addition, the die sizes and the dimensions of the steps may vary to accommodate the required package design. It is understood, therefore, that this invention is not limited to the particular embodiments disclosed, but covers modifications within the spirit and scope of the present invention as defined by the appended claims.

1. A stacked multichip package, comprising:
a base carrier having a top side and a bottom side;
a bottom integrated circuit die having a bottom surface attached to the base carrier top side, and an opposing, top surface, the top surface having a peripheral area including a plurality of first bonding pads and a central area;
a die attach material having particles blended therein dispensed onto the top surface of the bottom die in the central area; and
a top integrated circuit die having a bottom surface, wherein the top die is positioned over the bottom die and the bottom surface of the top die is attached to the top surface of the bottom die via the die attach material, wherein the particles blended into the die attach material maintain a predetermined spacing between the bottom die and the top die.

2. The stacked multichip package of claim 1, wherein the predetermined spacing is sufficient to allow wires wirebonded to the first bonding pads such that the wirebonds are not damaged when the top die is attached to the bottom die.

3. The stacked multichip package of claim 2, wherein the particles are blended into the die attach material after the die attach material is dispensed onto the central area of the top surface of the bottom die.

4. The stacked multichip package of claim 1, wherein the particles are generally circular in shape and have a diameter ranging from about 30 um to about 96 um

5. The stacked multichip package of claim 1, wherein the particles comprise a stable and inert material.

6. The stacked multichip package of claim 5, wherein the particles comprise one of silica and teflon.

7. The stacked multichip package of claim 1, wherein a ratio of particles to adhesive of the die attach is about 1:3.

8. The stacked multichip package of claim 1, wherein the top die and the bottom die are of similar size and shape.

9. The stacked multichip package of claim 1, wherein the top die is larger than the bottom die.

10. The stacked multichip package of claim 1, wherein the bottom die is electrically connected to the base carrier with first wires, the first wires having first ends electrically connected to the first bonding pads and second ends electrically connected to first leads on the top side of the base carrier.

11. The stacked multichip package of claim 10, wherein the top die includes a plurality of second bonding pads located in a peripheral area on a top surface of the top die and wherein the top die is electrically connected to the base carrier with second wires, the second wires having first ends electrically connected to the second bonding pads and second ends electrically connected to second leads on the top side of the base carrier.

12. The stacked multichip package of claim 11, further comprising an encapsulant covering the top and bottom dice, the first and second wires, and at least a portion of the top side of the base carrier.

13. A stacked multichip package, comprising:
a base carrier having a top side and a bottom side, the top side including a plurality of first leads and a plurality of second leads;
a bottom integrated circuit die having a bottom surface attached to the base carrier top side, and an opposing, top surface, the top surface having a peripheral area including a plurality of first bonding pads and a central area, wherein the bottom die is electrically connected to the base carrier with first wires, the first wires having first ends electrically connected to respective ones of the first bonding pads and second ends electrically connected to respective ones of the first leads;
an adhesive material having particles blended therein dispensed on the top surface of the bottom die in the central area;
a top integrated circuit die having a bottom surface, wherein the top die is positioned over the bottom die and the bottom surface of the top die is attached to the top surface of the bottom die via the adhesive material, wherein the particles blended into the adhesive material maintain a predetermined spacing between the bottom die and the top die, the top die includes a plurality of second bonding pads located on a top surface thereof and the top die is electrically connected to the base carrier with second wires, the second wires having first ends electrically connected to respective ones of the second bonding pads and second ends electrically connected to respective ones of the second leads; and
an encapsulant covering the first and second dice, the first and second wires, and at least a portion of the top side of the base carrier.

14. The stacked multichip package of claim 13, wherein the top die and the bottom die are of similar size and shape.

15. The stacked multichip package of claim 13, wherein the top die is larger than the bottom die.

16. The stacked multichip package of claim 13, wherein the particles within the adhesive material are generally circular in shape and have a diameter ranging from about 30 um to about 96 um.

17. The stacked multichip package of claim 16, wherein the adhesive material has a ration of particles to adhesive of about 1:3.

18. The stacked multichip package of claim 13, wherein the particles comprise one of silicon and teflon.

19. The stacked multichip package of claim 13, wherein the predetermined spacing between the top die and the bottom die maintained by the adhesive material is sufficient to protect the electrical connections between the first wires and the first bonding pads from being damaged by the attachment of the top die to the bottom die.

20. A method of making a stacked multichip package comprising the steps of:
attaching a bottom integrated circuit die to a base carrier, the bottom die having a bottom surface and a top surface, the top surface having a central area and a peripheral area, the peripheral area including a plurality of first bonding pads, wherein the bottom surface of the bottom die is attached to a top side of the base carrier;
electrically connecting the bottom die to the base carrier by wirebonding first wires to respective ones of the plurality of first bonding pads of the bottom die and to corresponding first leads on the top side of the base carrier;
dispensing an adhesive material onto the central area of the top surface of the bottom die;
dispensing a plurality of particles onto the adhesive material to provide the adhesive material with a predetermined height;
attaching a bottom surface of a top die to the top surface of the bottom die with the adhesive material, the top die having a plurality of second bonding pads located on a top surface thereof, wherein the dispensed particles cause the top die to be spaced from the bottom die such that the top die does not contact the first wires; and
electrically connecting the top die to the base carrier by wirebonding second wires to respective ones of the plurality of second bonding pads and to corresponding second leads on the base carrier.

21. The method of making a stacked multichip package of claim 20, wherein the step of dispensing the particles onto the adhesive material comprises using a compressed gas to pump the particles from a particle container onto the adhesive material.

22. The method of making a stacked multichip package of claim 20, wherein the step of dispensing the particles onto the adhesive material comprises using a vacuum force to pick up the particles from a fluid bath of particles.

23. The method of making a stacked multichip package of claim 20, wherein the particles are blended with the adhesive material in a container and then the adhesive material and particles are dispensed onto the central area of the bottom die in a single dispensing step.

24. The method of making a stacked multichip package of claim 20, wherein the bottom and top dice have substantially the same length and substantially the same width.

25. The method of making a stacked multichip package of claim 20, wherein the top die is larger than the bottom die.

26. The method of making a stacked multichip package of claim 20, further comprising the step of encapsulating the top and bottom dice, the first and second wires, and at least a portion of the base carrier with a resin.
